(19) United States
(12) Patent Application Publication
(10) Pub. No.: US 2022/0181866 A1
(43) Pub. Date: Jun. 9, 2022

(54) METHOD FOR FAST-DETECTION OF PEAK FAULT CURRENT

(71) Applicant: S&C Electric Company, Chicago, IL (US)

(72) Inventors: Todd W. Klippel, Oak Park, IL (US); Alejandro Montenegro, Chicago, IL (US)

(73) Assignee: S&C Electric Company, Chicago, IL (US)

(21) Appl. No.: 17/524,167

(22) Filed: Nov. 11, 2021

Related U.S. Application Data
(60) Provisional application No. 63/122,613, filed on Dec. 8, 2020.

(51) Int. Cl. H02H 3/08; H02H 7/122; H02H 7/28

(52) U.S. Cl. CPC H02H 3/08; H02H 7/28; H02H 7/1227

(57) ABSTRACT

A system and method for quickly detecting fault current on a power line in an electrical power distribution network. A switch assembly includes a detecting circuit for quickly detecting the fault current on the power line. The circuit includes a Rogowski coil wrapped around the power line that provides an output measurement signal that is proportional to a change in the current flow on the line, and a passive integrator responsive to the output measurement signal from the Rogowski coil that integrates the output measurement signal over time. The circuit also includes an amplifier responsive to and amplifying the integrated output measurement signal and a microcontroller responsive to the amplified output measurement signal that calculates the current flow on the line using the amplified output measurement signal. A current transformer harvests energy from the power line to power the circuit when the fault current is occurring.

### CROSS-REFERENCE TO RELATED APPLICATION

This application claims the benefit of priority from the U.S. Provisional Application No. 63/122,613, filed on Dec. 8, 2020, the disclosure of which is hereby expressly incorporated herein by reference for all purposes.

### BACKGROUND

### Field

This disclosure relates generally to a system and method for quickly detecting fault current in an electrical power distribution network and, more particularly, to a fault current detecting circuit that is part of a vacuum interrupter switch assembly employed in an electrical power distribution network.

### Discussion of the Related Art

An electrical power distribution network, often referred to as an electrical grid, typically includes a number of power generation plants each having a number of power generators, such as gas turbines, nuclear reactors, coal-fired generators, hydro-electric dams, etc. The power plants provide power at a variety of medium voltages that are then stepped up by transformers to a high voltage AC signal to be connected to high voltage transmission lines that deliver electrical power to a number of substations typically located within a community, where the voltage is stepped down to a medium voltage for distribution. The substations provide the medium voltage power to a number of three-phase feeders including three single-phase feeder lines that carry the same current, but are 120° apart in phase. A number of three-phase and single phase lateral lines are tapped off of the feeder that provide the medium voltage to various distribution transformers, where the voltage is stepped down to a low voltage and is provided to a number of loads, such as homes, businesses, etc.

Power distribution networks of the type referred to above typically include a number of switching devices, breakers, reclosers, interrupters, etc. that control the flow of power throughout the network. A vacuum interrupter is a switch that has particular application for many of these types of devices. A vacuum interrupter employs opposing contacts, one fixed and one movable, positioned within a vacuum enclosure. When the vacuum interrupter is opened by moving the movable contact away from the fixed contact to prevent current flow through the interrupter the arc that is created between the contacts is extinguished by the vacuum at the next zero current crossing. A vapor shield is typically provided around the contacts to collect the emitted metal vapor caused by the arcing. In some designs, the vacuum interrupter is encapsulated in a solid insulation housing that has a grounded external surface.

Periodically, faults occur in the distribution network as a result of various things, such as animals touching the lines, lightning strikes, tree branches falling on the lines, vehicle collisions with utility poles, etc. Faults may create a short-circuit that increases the stress on the network, which may cause the current flow to significantly increase, for example, many times above the normal current, along the fault path. This amount of current causes the electrical lines to significantly heat up and possibly melt, and also could cause mechanical damage to various components in the network. These faults are often transient or intermittent faults as opposed to a persistent or bolted fault, where the thing that caused the fault is removed a short time after the fault occurs, for example, a lightning strike. In such cases, the distribution network will almost immediately begin operating normally after a brief disconnection from the source of power.

Fault interrupters, for example, reclosers that employ vacuum interrupters, are provided on utility poles and in underground circuits along a power line and have a switch to allow or prevent power flow downstream of the recloser. These reclosers typically detect the current and/or voltage on the line to monitor current flow and have controls that indicate problems with the network circuit, such as detecting a high current fault event. For example, a vacuum interrupter may employ a Rogowski coil, well known to those skilled in the art, that is wrapped around the power line and measures a change in current flow on the line by means of the voltage that is induced in the coil being proportional to the rate of change of current flow. If such a high fault current is detected the recloser is opened in response thereto, and then after a short delay closed to determine whether the fault is a transient fault. If high fault current flows when the recloser is closed after opening, it is immediately re-opened. If the fault current is detected a second time, or multiple times, during subsequent opening and closing operations indicating a persistent fault, then the recloser remains open, where the time between detection tests may increase after each test. For a typical reclosing operation for fault detection tests, about 3-6 cycles or 50 to 100 ms of fault current pass through the recloser before it is opened, but testing on delayed curves can allow fault current to flow for much longer times, which could cause significant stress on various components in the network. However, certain recloser type devices, such as those designed to replace fuses, are required to detect fault current and open the vacuum interrupter within a half of a cycle. To be able to perform a half-cycle interruption, the control does not have time to perform a Fourier transform on the sampled current, and must rely on individual sampled current measurements being above a threshold.

It is possible for an electronically-controlled fault-interrupting recloser employing a vacuum interrupter of the type being discussed herein, or other type of fault-interrupting unit, that is powered from line current, a battery or other limited-power source, to be unpowered when fault current occurs. For example, if the vacuum interrupter electronics are powered by an energy harvesting current transformer that steps down the line current, the normal current level on the line may not be high enough to provide enough current on the secondary winding of the current transformer to power the electronics, but fault current will provide enough current. When fault current occurs, the unit will require a few milliseconds to start-up the control processor before it can begin sampling or measuring current. When a Rogowski coil is used in the vacuum interrupter as the current sensor, its output is proportional to the rate of current change (di/dt), and thus there is a 90° phase shift from the actual current (˜4 ms for 60 Hz). Therefore, if the unit begins powering up around the zero crossing of the fault current when the di/dt measurement is at its peak, because of the processor power up time, when it begins sampling around the peak fault current, the di/dt measurement from the Rogowski coil will be at its minimum and won't detect the fault current. Thus, it will require another 4 ms before the processor can detect the fault current peak, which prevents the fault current from being detected and the vacuum interrupter opening within the desired time frame. In other words, this delay in detecting the fault current is too long if the unit needs to perform a single-cycle or half-cycle current interruption to reduce the amount of energy that passes through the unit during a fault condition.

### SUMMARY

The following discussion discloses and describes a system and method for quickly detecting fault current on a power line in an electrical power distribution network. A switch assembly, such as a vacuum interrupter switch assembly associated with a recloser, includes a detecting circuit for quickly detecting the fault current on the power line. The circuit includes a Rogowski coil wrapped around the power line that provides an output measurement signal that is proportional to a change in current flow (di/dt) on the line, and a passive integrator responsive to the output measurement signal from the Rogowski coil that integrates the output measurement signal over time. The circuit also includes an amplifier responsive to and amplifying the integrated output measurement signal and a microcontroller responsive to the amplified output measurement signal that calculates the current flow on the line using the amplified output measurement signal. A current transformer harvests energy from the power line to power the circuit when the fault current is occurring.

Additional features of the disclosure will become apparent from the following description and appended claims, taken in conjunction with the accompanying drawings.

### BRIEF DESCRIPTION OF THE DRAWINGS

FIG. 1 is a schematic diagram of a power distribution network;

FIG. 2 is an isometric view of a switch assembly connected to a pole mounted insulator and including a vacuum interrupter;

FIG. 3 is a graph with time on the horizontal axis and current on the vertical axis illustrating the timing of system fault current versus signal sampling; and

FIG. 4 is schematic diagram of a fault current detecting circuit that is part of a vacuum interrupter including a Rogowski coil that measures a change in current flow (di/dt) on a power line and a passive integrator that integrates the measured signal.

### DETAILED DESCRIPTION OF THE EMBODIMENTS

The following discussion of the embodiments of the disclosure directed to a fault current detecting circuit that is part of a vacuum interrupter switch assembly employed in an electrical power distribution network, where the circuit includes a Rogowski coil for measuring a change in current flow (di/dt) on a power line and a passive integrator for integrating the measured signal while a microcontroller is being powered up, is merely exemplary in nature, and is in no way intended to limit the disclosure or its applications or uses. For example, the discussion herein refers to the detecting circuit as being part of a recloser having a vacuum interrupter. However, as will be appreciated by those skilled in the art, the switch assembly will have other applications.

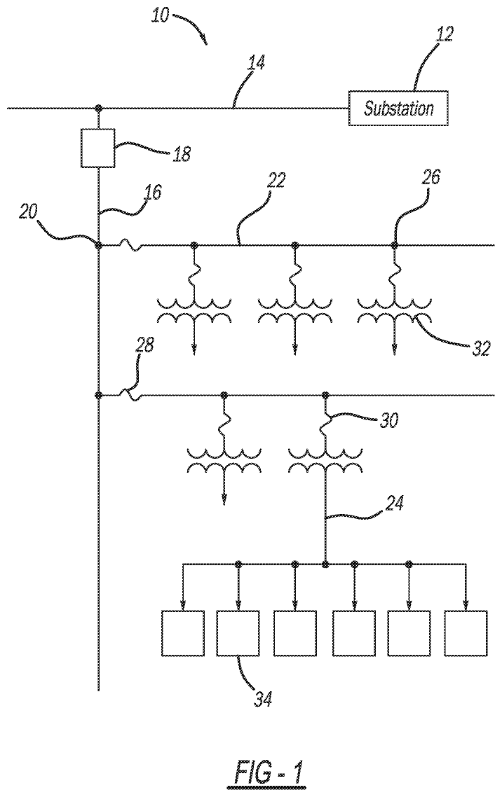

FIG. 1 is a schematic type diagram of an electrical power distribution network 10 including an electrical substation 12 that steps down high voltage power on a high voltage power line (not shown) to medium voltage power, such as 12-47 kV, provided on a substation bus 14. A three-phase feeder 16 is connected to the bus 14 and a recloser 18 is provided proximate the connection point between the feeder 16 and the bus 14. The recloser 18 is intended to represent any reclosing or fault interrupter device of the type discussed above, and would typically include a vacuum interrupter for opening and closing the recloser 18 to allow or prevent current flow therethrough on the feeder 16, possibly sensors for measuring the current and/or voltage of the power signal propagating on the feeder 16, a controller for processing the measurement signals and controlling the position of the interrupter, and a transceiver for transmitting data and messages to a control facility (not shown) and/or to other reclosers and components in the network 10. The network 10 includes a number of single-phase lateral lines 22 coupled to the feeder 16 usually at a utility pole 20 and a number of a secondary service lines 24 coupled to each lateral line 22 usually at a utility pole 26, where a lateral fuse 28 is provided at the connection point between each lateral line 22 and the feeder 16 and a primary fuse 30 is provided at the connection point between each lateral line 22 and each service line 24. A distribution transformer 32 is provided at the beginning of each service line 24 that steps down the voltage from the medium voltage to a low voltage to be provided to loads 34, such as homes.

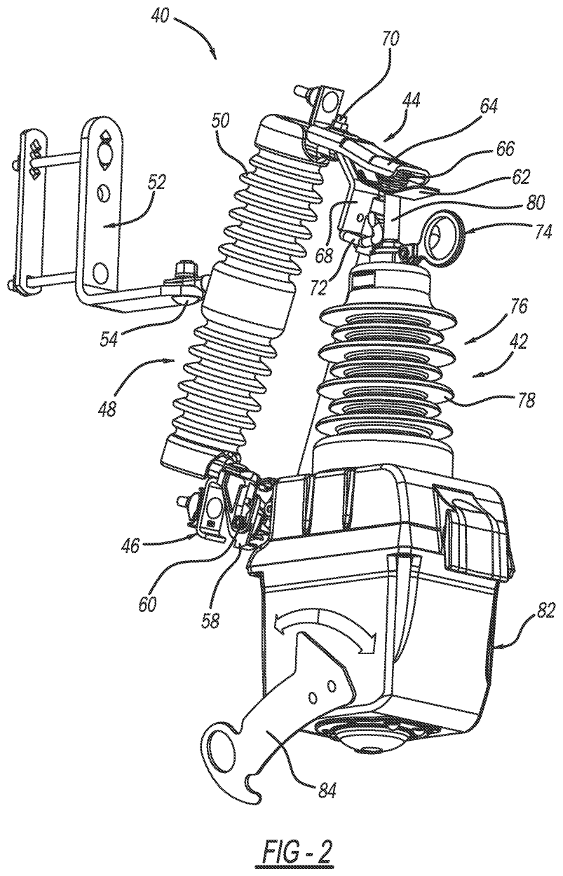

FIG. 2 is an isometric view of a pole mounted switch assembly 40 including a single phase self-powered magnetically actuated switching device 42 intended to represent any suitable device including components for use as the recloser 18 or devices that can be used instead of the fuses 28 and 30. The switching device 42 is coupled to a mounting assembly 44 at one end and a mounting hinge 46 at an opposite end. The mounting assembly 44 is secured to one end of an insulator 48 having skirts 50 and the mounting hinge 46 is secured to an opposite end of the insulator 48, where the insulator 48 is mounted to a bracket 52 by a bolt 54 that may be attached to a utility pole (not shown). The mounting hinge 46 includes a channel catch 58 that accepts a trunnion rod 60 coupled to the device 42 and that is electrically coupled to a unit bottom contact (not shown). The mounting assembly 44 includes a top mounting tab 62, an extension tab 64 and a spring 66 positioned between the tabs 62 and 64. The mounting assembly 14 also includes a support tab 68 bolted to the extension tab 64 by a bolt 70 and a pair of mounting horns 72 coupled to and extending from the support tab 68 opposite to the extension tab 64. A guiding pull ring member 74 is coupled to a top of the device 42 and allows a worker to easily install and remove the device 42 from the utility pole pulling on the ring member 74 to disconnect the device 42 from the mounting assembly 44, rotating the device 42 outward on the trunnion rod 60 and then lifting the device 42 out of the catch 58. Although the device 42 is shown and described herein as being mounted to a utility pole, it is noted that this is by way of a non-limiting example in that the device 42 may have application for other locations in a medium voltage power network, such as in a pad mounted or sub-surface switchgear.

The switching device 42 includes a vacuum interrupter 76 having an outer insulation housing 78 that encloses vacuum interrupter switch contacts (not shown) of the type referred to above, where the vacuum interrupter 76 can be any vacuum interrupter known in the art for medium voltage uses that is suitable for the purposes discussed herein. More particularly, the vacuum interrupter 76 defines a vacuum chamber that encloses a fixed contact (not shown) that is electrically coupled to a unit top contact 80 and a movable contact (not shown) that is electrically coupled to the unit bottom contact, where the fixed and movable contacts are in contact with each other within the vacuum chamber when the vacuum interrupter 76 is closed. When the vacuum interrupter 76 is opened by moving the movable contact away from the fixed contact the arc that is created between the contacts is extinguished by the vacuum at a zero current crossing. The switching device 42 also includes an enclosure 82 that encloses a magnetic actuator or other device that opens and closes the vacuum interrupter 76, a Rogowski coil for measuring current on the power line, various processors, electronics and circuits, energy harvesting devices, sensors, communications devices, etc. consistent with the discussion herein. A lever 84 provides manual control of the open and close operation of the switching device 42.

As will be discussed in detail below, this disclosure proposes a fault detection circuit that detects fault current on a power line and has particular application as being part of a vacuum interrupter switch assembly. The circuit includes a Rogowski coil, a passive integrator and a microcontroller, where the integrator provides passive integration directly to the measured change in current flow from the Rogowski coil so that the phase-shift and subsequent delay of the output referred to above is removed. It is assumed that during fault conditions any harmonics are dominated by the 60 Hz component, which allows the usage of integrated Rogowski coil signal measurements to determine fault conditions. Since the integration is completely passive, the signal integration occurs while the microcontroller is being energized and boots up, and is available at its full magnitude when the microcontroller wakes up and begins sampling, and thus has a signal that is directly proportional to the current.

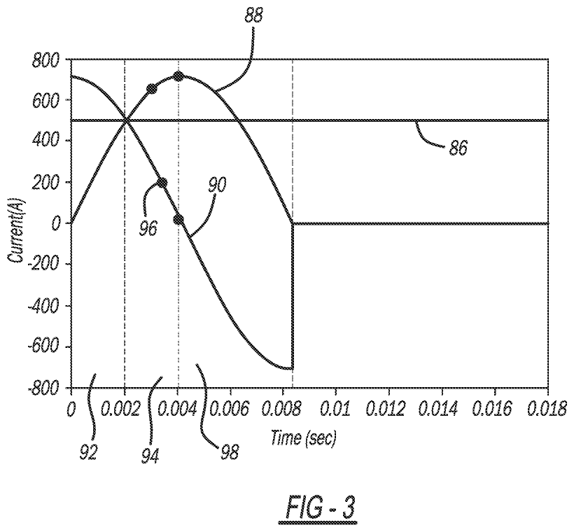

FIG. 3 is a graph with time on the horizontal axis and current on the vertical axis illustrating the timing of system fault current versus signal sampling for a 500 A symmetrical fault current threshold, represented by line 86, where fault current is shown by graph line 88 and a proportional change in the current flow measurement signal (di/dt) from the output of a Rogowski coil is shown by graph line 90. This illustrates the 90° phase shift or delay between the current and the output of the Rogowski coil in that when the fault current is at its peak, the di/dt current measurement of the coil is at a minimum and when the fault current has a zero crossing the di/dt current measurement of the coil is at its maximum. During the first 2 ms after the fault current occurs, shown in section 92, the microcontroller is powering up from, for example, power provided by a current transformer that receives power from the fault current, and no samples can be taken. However, this time period corresponds to the maximum output of the Rogowski coil. By the time the microcontroller has powered-up and begun taking samples 96 in section 94, the output of the Rogowski coil has fallen below the 500A threshold and the individual samples 96 will not detect fault current. By integrating the Rogowski coil output during the time that the microcontroller is waking up as discussed herein removes the phase shift and filters the high-frequency components, allowing the microcontroller to obtain the sample 96 proportional to the fault current waveform once it has booted up. This waveform doesn't reach its peak until after the microcontroller has powered-up and begun sampling, thus removing the delay. Because the control can initially be unpowered, the integration elements must be completely passive, which is accomplished by using a capacitor to integrate the signal. The vacuum interrupter is commanded open at 0.004 milliseconds, but it takes the interrupter 0.004 milliseconds to fully open through section 98, which it does at about 0.0083 milliseconds, which is about one-half cycle. Without the integration of the Rogowski coil output while the microcontroller is waking up, it would take another current cycle for the vacuum interrupter to open.

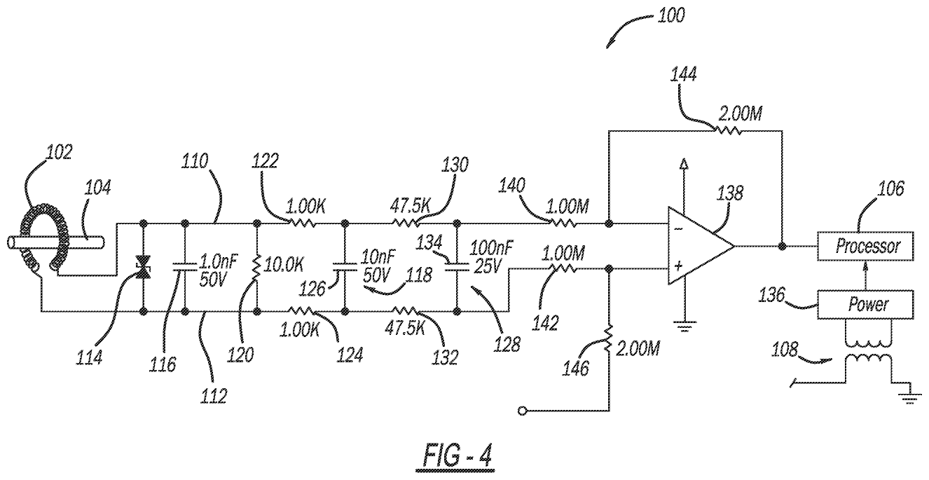

FIG. 4 is schematic diagram of a fault current detecting circuit 100 including a Rogowski coil 102 that measures a change in current flow through a power line 104 by means of the voltage that is induced in the coil 102 being proportional to the rate of change of the current flow in a manner well understood by those skilled in the art. The circuit 100 also includes a microcontroller 106 that samples the measured current, where the microcontroller 106 is powered by a power circuit 136 that receives power from a current transformer 108 that harvests energy from the line 104 and is only able to provide power when source current is present. The AC analog current measurement signal from the Rogowski coil 102 is provided on first and second rails 110 and 112 of the circuit 100 and is first sent to a diode 114 and a capacitor 116 to provide transient protection, then to a base load resistor 120, and then through a high-frequency filter 118 including resistors 122 and 124 and a capacitor 126 to remove high frequency noise. The filtered current measurement signal is then sent to a passive RC integrator 128 including a resistors 130 and 132 and a capacitor 134 that passively integrates or accumulates charge from the signal while the microcontroller 106 is being powered up in response to the fault current, where the integrator 128 has a frequency response of:

$$\frac{{V}_{O}}{{V}_{I}} = \frac{1}{1 + s ( R 1 + R 2 ) C}$$

and where R1 is the resistance of the resistor 130, R2 is the resistance of the resistor 132 and C is the capacitance of the capacitor 134.

The integrated current signal from the capacitor 134 is then sent to the negative input terminal and the positive input terminal of a differential amplifier 138 that is set-up in a full differential configuration for amplifying the integrated current signal, where the output of the amplifier 138 is provided to the microcontroller 106. A feedback resistor 144 is provided in a feedback line from the output of the amplifier 138 to the negative input terminal of the amplifier 138 and a reference resistor 146 is provided in a line that provides a reference voltage to the positive input terminal of the amplifier 138. It is noted that although drift over time is controlled by the resistors 120, 122, 124, 130 and 132, it is not important to prevent drifting of the integrator 128 over time, since this signal is only used during the first ½ cycle of a fault condition during power up. In other words, once the microcontroller 106 is powered up, the signal at the output of the filter 118 can be provided directly to the microcontroller 106 for current measurement purposes.

Generally, most active electronic components have transient protection at their terminals that couple to the power supply rails. When these devices are not powered, this protection can present low-impedance at the terminals. This is a problem for the passive integrator 128 as this impedance will be in parallel with the integrating capacitor 134. Therefore, high passive impedance resistors 140 and 142, for example, 1 MΩ, are provided between the capacitor 134 and the input terminals of the amplifier 138 to preserve the integration ability of the capacitor 134 before the microcontroller 106 is powered up.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A current detecting circuit for measuring current flow on an electrical line, the circuit comprising:
a Rogowski coil wrapped around the line and providing an output measurement signal that is proportional to a change in current flow on the line;
a passive integrator responsive to the output signal from the Rogowski coil, the passive integrator integrating the output signal over time;
an amplifier responsive to and amplifying the integrated output measurement signal; and
a microcontroller responsive to the amplified and integrated output measurement signal, the microcontroller calculating the current flow on the line using the amplified output measurement signal.

2. The circuit according to claim 1 wherein the circuit is part of a switch assembly in a power distribution network.

3. The circuit according to claim 2 wherein the circuit detects fault current on a power line in the network.

4. The circuit according to claim 2 wherein the switch assembly includes a vacuum interrupter.

5. The circuit according to claim 2 wherein the switch assembly is part of a self-powered magnetically actuated recloser.

6. The circuit according to claim 1 wherein the amplifier is a differential amplifier.

7. The circuit according to claim 1 wherein a high impedance resistor is provided at positive and negative input terminals of the amplifier.

8. The circuit according to claim 1 wherein the passive integrator includes two resistors and a capacitor.

9. The circuit according to claim 1 further comprising a high frequency filter that filters out high frequency noise in the output measurement signal before the signal is integrated.

10. The circuit according to claim 1 further comprising a diode and a capacitor that provide transient protection.

11. The circuit according to claim 1 further comprising a current transformer, the current transformer harvesting energy from the line to power the circuit.

12. A vacuum interrupter for controlling power flow on a power line in an electrical power distribution network, the vacuum interrupter including a fault current detecting circuit for detecting fault current on the power line, the circuit comprising:
a Rogowski coil wrapped around the power line and providing an output measurement signal that is proportional to a change in the current flow on the line;
a passive integrator responsive to the output measurement signal from the Rogowski coil, the passive integrator integrating the output measurement signal over time;
an amplifier responsive to and amplifying the integrated output measurement signal;
a microcontroller responsive to the amplified output measurement signal, the microcontroller calculating the current flow on the line using the amplified output measurement signal; and
a current transformer for harvesting energy from the power line to power the circuit when fault current is occurring.

13. The vacuum interrupter according to claim 12 wherein the switch assembly is part of a self-powered magnetically actuated recloser.

14. The vacuum interrupter according to claim 12 wherein the amplifier is a differential amplifier.

15. The vacuum interrupter according to claim 12 wherein a high impedance resistor is provided at positive and negative input terminals of the amplifier.

16. The vacuum interrupter according to claim 12 wherein the integrator includes two resistors and a capacitor.

17. The vacuum interrupter according to claim 12 further comprising a high frequency filter that filters out high frequency noise in the output measurement signal before the signal is integrated.

18. The vacuum interrupter according to claim 12 further comprising a diode and a capacitor that provide transient protection.

19. A current detecting circuit for measuring current flow on an electrical line, the circuit comprising:
a current sensor providing an output measurement signal that is proportional to a change in the current flow on the line;
a passive integrator responsive to the output measurement signal from the current sensor, the passive integrator integrating the output measurement signal over time; and
a microcontroller responsive to the integrated output measurement signal, the integrator integrating the current measurement signal while the microcontroller is being powered up and the microcontroller calculating the current flow on the line using the integrated output measurement signal after it is powered up.

20. The circuit according to claim 19 wherein the current sensor is a Rogowski coil.
